(19) United States
(12) Patent Application Publication
(10) Pub. No.: US 2004/0139917 A1
(43) Pub. Date: Jul. 22, 2004

(54) Plasma processing apparatus

(76) Inventors: Naoshi Yamaguchi, Osaka-shi (JP); Teiichi Kimura, Itami-shi (JP); Yoshihiro Yanagi, Neyagawa-shi (JP); Kazuhiro Yoshida, Izumi-shi (JP); Hideo Haraguchi, Toyonaka-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/685,459

(22) Filed: Oct. 16, 2003

(30) Foreign Application Priority Data
Oct. 17, 2002 (JP) 2002-303502

(51) Int. Cl. C23C 16/00

(52) U.S. Cl. 118/728

(57) ABSTRACT

Provided is a plasma processing apparatus, which is loaded with a substrate to be processed on the voltage-applied electrode side and is able to achieve a uniform plasma processing characteristic on a substrate surface by correcting the distortion of an electric field in the edge portion and the distortion of plasma. There is provided a plasma processing apparatus, which introduces a processing gas into a processing chamber and excites a plasma in the processing chamber to carry out plasma processing on a substrate to be processed placed on a cathode electrode inside the processing chamber, the apparatus being provided with a ring that encompasses the outer peripheral edge portion of the substrate and has a clearance between its encompassing surface and the upper surface and the outer peripheral edge of the substrate.

### BACKGROUND OF THE INVENTION

The present invention relates to a plasma processing apparatus for a semiconductor manufacturing apparatus or an LCD manufacturing apparatus.

A plasma processing apparatus for a semiconductor manufacturing apparatus or an LCD manufacturing apparatus generates an electric field in a vacuum vessel by supplying a high-frequency power to either one or both of a plasma source and an electrode inside the vacuum vessel while controlling the inside of the vacuum vessel to a prescribed pressure by supplying gas into the vacuum vessel and evacuating the inside of the vacuum vessel, the electric field transforming a reactive gas into a plasma to plasma-process a substrate placed on the electrode inside the vacuum vessel. In this case, when the substrate is placed on the cathode electrode side to which the high-frequency power is applied, it becomes difficult to obtain a plurality of plasma processing characteristics uniformly on the surface of the substrate unless a plasma sheath on the substrate surface is uniformly distributed with respect to the substrate surface, inevitably causing a variation to some extent in the plasma characteristics on the substrate surface in practice. In particular, the plasma sheath on the substrate surface becomes excessively increased at the outer peripheral edge portion of the substrate, and when the plasma processing characteristics are obtained in correspondence with the distribution of the plasma sheath, the characteristics are to directly receive influence. For example, in a dry etching apparatus, an etching rate has had the tendency of becoming increased in the peripheral portion than in the center portion.

Accordingly, there has been a technique for reducing the variation in the etching rate with a reduced reaction rate of the outer peripheral portion of the substrate by making a ring of which the height from the substrate surface is not constant throughout the entire circumference stand around the substrate so that the ring surrounds the substrate at a distance located uniformly apart from the substrate and controlling the inflow of a reactive gas to the peripheral portion of the substrate and the outflow of substances produced through the reaction as a method for obtaining a uniform plasma processing characteristic on the substrate surface, the characteristic receiving influence from the distribution of the plasma sheath (refer to, for example, Unexamined Japanese Patent Publication No. 2000-315676).

Next, the conventional dry etching apparatus described in the above Publication will be described with reference to FIGS. 8 and 9. As shown in FIG. 8, the conventional dry etching apparatus described in the above Publication generates a plasma in a vacuum vessel 111 by supplying high-frequency powers to a lower electrode 115 and a plasma source 117 by means of a high-frequency power supply 114 for the electrode and a high-frequency power supply 118 for the plasma source while the vacuum vessel 111 is internally maintained at a prescribed pressure by introducing gas at a prescribed flow rate from a gas supply unit 112 into the vacuum vessel 111 and carrying out evacuation by means of a vacuum pump 113 as an evacuating unit, so that an etching process is carried out on a substrate 116 placed on the lower electrode 115. By carrying out the processing with the placed ring 119 provided, which surrounds the entire circumference of the substrate 116 around the substrate 116 and of which the height from the surface of the substrate 116 is not constant throughout the entire circumference, there is carried out dry etching, which is able to selectively suppress the etching rate in the periphery of the substrate 116 and, in particular, corner portions with respect to the center portion and to obtain a uniform etching rate as a whole.

This technique has conventionally obtained a uniformity of etching rate by means of a focus ring of a prescribed height and is characterized in that the ring of which the height from the substrate surface is not uniform throughout the entire circumference is provided to obtain a further uniformity of etching rate in view of the diversification of etching processes.

However, this method is an approach to correct the variation of the plasma processing characteristic ascribed to the distribution of the plasma sheath due to the electric field by the flow control of the reactive gas, and the variation of the distribution of the plasma sheath still exists, providing no drastic solution.

Normally, if a cathode electrode surface of a large size such that the electrode outermost edge portion can be ignored is supposed and a high-frequency power is applied to the center of the electrode, then there is resulting a distribution such that the electric field generated on the cathode electrode surface has a highest point at the point to which the power is applied and gently reduces outwardly of the cathode electrode, and the plasma processing characteristic of the substrate also receives influence from this distribution. The plasma sheath generated on the surface of the substrate is generated in correspondence with the electric field distribution on the cathode electrode, and they do not always coincide with each other in practice. The above is because the cathode electrode is normally designed to have dimensions somewhat larger than the substrate and the substrate is placed on the cathode electrode or the cathode electrode is designed to have dimensions somewhat smaller than the substrate and the substrate is placed on the cathode electrode. Therefore, even if the high-frequency power is uniformly applied to the cathode electrode surface and a uniform electric field is generated on the cathode electrode surface, the outer peripheral edge portion of the substrate is located inside the cathode electrode surface in the former case, and vice versa in the latter case. In either case, the electric field generated in the outer peripheral edge portion of the substrate is distorted since the electric field generated in the outer peripheral edge portion of the substrate cannot avoid suffering a change in configuration due to the thickness of the substrate and a change in impedance due to the material of the substrate to be processed, and the plasma sheath in the neighborhood of the outer peripheral edge portion of the substrate is excessively increased. Furthermore, if the dimension of the substrate and the dimension of the cathode electrode are designed to be same, then the change in configuration and the change in impedance become more significant than in the above-mentioned case, and therefore, the plasma sheath in the neighborhood of the outer peripheral edge portion of the substrate is increased further than in the above-mentioned case. For this reason, there has been an issue that the plasma processing characteristic is more excessively varied in the outer peripheral edge portion of the substrate to be processed than in the inner surface portion of the substrate to be processed, failing in achieving uniform processing.

### SUMMARY OF THE INVENTION

Therefore, an object of the present invention is to provide a plasma processing apparatus with a substrate to be processed loaded on a voltage-applied electrode side, capable of achieving uniform plasma processing characteristic on a substrate surface by correcting distortion of an electric field in an edge portion and distortion of plasma.

The plasma processing apparatus of the present invention is a plasma processing apparatus characterized in that a ring that encompasses the outer peripheral edge portion of the substrate is provided. With this arrangement, the change in configuration due to the thickness of the substrate and the change in impedance due to the material of the substrate can be corrected. That is, the present invention is characterized in that a ring is provided so as to encompass the outermost peripheral edge portion of the substrate for the purpose of shielding or alleviating the electric field on the upper surface of the outer peripheral edge portion of the substrate and the surface in the vertical direction of the outer peripheral edge portion of the substrate in order to correct the electric field in the neighborhood of the upper surface of the outer peripheral edge portion of the substrate. Furthermore, if the ring is brought in direct contact with the substrate, then the impedance of the substrate itself is changed due to the contact with the ring. Therefore, the present invention is characterized in that a clearance is provided between the substrate and an encompassing surface of the ring in order to secure a certain distance between them so as not to bring the substrate in direct contact with the ring.

The above-mentioned arrangement enables the generation of a uniform electric field, the restraint of the phenomenon that the plasma sheath excessively increases in the neighborhood of the outer peripheral edge portion of the substrate, the restraint of the occurrence of variation of the plasma processing characteristic in the outer peripheral edge portion of the substrate to be processed, and the achievement of uniform processing.

### BRIEF DESCRIPTION OF THE DRAWINGS

These and other aspects and features of the present invention will become clear from the following description taken in conjunction with the preferred embodiments thereof with reference to the accompanying drawings, in which:

FIG. 1A is a partially-sectional side view showing the whole of a plasma processing apparatus according to a first embodiment of the present invention;

FIG. 1B is a plan view showing a ring of the plasma processing apparatus according to the first embodiment of the present invention;

FIG. 1C is an enlarged, partially-sectional side view showing the ring and a cathode electrode etc. of the plasma processing apparatus according to the first embodiment of the present invention with viewed in a direction of an arrow A of FIG. 1B;

FIG. 2A is an enlarged, partially-sectional side view showing a ring and a cathode electrode etc. of a plasma processing apparatus according to a second embodiment of the present invention;

FIG. 2B is a plan view showing a ring of a plasma processing apparatus according to a modification of the second embodiment of the present invention;

FIG. 2C is an enlarged, partially-sectional side view showing the ring and a cathode electrode etc. of a plasma processing apparatus according to the modification of the second embodiment of the present invention with viewed in a direction of an arrow B of FIG. 2B;

FIG. 3A is an enlarged, partially-sectional side view showing a ring and a cathode electrode etc. of a plasma processing apparatus according to a third embodiment of the present invention;

FIG. 3B is an enlarged, partially-sectional side view showing a ring and a cathode electrode etc. of a plasma processing apparatus according to a modification of the third embodiment of the present invention;

FIG. 4A is a plan view for explaining a state where a substrate is conveyed by a substrate conveyance mechanism in the plasma processing apparatus according to the modification of the third embodiment of the present invention;

FIG. 4B is an enlarged, partially-sectional side view for explaining the state where the substrate is conveyed by the substrate conveyance mechanism in the plasma processing apparatus according to the modification of the third embodiment of the present invention;

FIG. 5 is an enlarged, partially-sectional side view showing a plasma processing apparatus according to a fourth embodiment of the present invention;

FIG. 6 is an enlarged, partially-sectional side view showing a plasma processing apparatus according to a fifth embodiment of the present invention;

FIGS. 7A and 7B are graphs showing etching rates when silicon nitride film substrates are etched in Ar gas by means of dry etching apparatuses for LCD capable of coping with 550 mm×670 mm substrates in a plasma processing apparatus to which the present invention is not adopted and in the plasma processing apparatus according to the first embodiment of the present invention;

FIG. 8 is an enlarged, partially-sectional side view showing a conventional plasma processing apparatus; and

FIG. 9 is a perspective view showing a conventional ring.

### DETAILED DESCRIPTION OF THE PREFERRED EMBODIMENTS

Before the description of the present invention proceeds, it is to be noted that like parts are designated by like reference numerals throughout the accompanying drawings.

Before explaining various kinds of embodiments of the present invention, various kinds of aspects of the present invention will be described first.

According to a first aspect of the present invention, there is provided a plasma processing apparatus, for introducing a processing gas into a processing chamber and exciting a plasma in the processing chamber to carry out plasma processing on a substrate to be processed placed on a cathode electrode inside the processing chamber,

the apparatus comprising a ring for encompassing an outer peripheral edge portion of the substrate in proximity to the outer peripheral edge portion of the substrate, the ring having a clearance between its encompassing surface and an upper surface of the substrate. Providing the ring that has the clearance between the ring and the upper surface and the outer peripheral edge of the substrate has the operation of enabling the correction of the etching rate of the outer peripheral portion of the substrate to uniformly generate an electric field, restraining the excessive increase of the plasma sheath in the neighborhood of the outer peripheral edge portion of the substrate and the occurrence of variation of the plasma processing characteristic and allowing the achievement of uniform plasma processing.

According to a second aspect of the present invention, there is provided the plasma processing apparatus as claimed in the first aspect, wherein the cathode electrode has a substrate placement surface having larger than the substrate, and the ring is placed on the substrate placement surface of the cathode electrode and has an L-figured shape directed in a direction in which a cross-section shape of the ring is able to encompass the outer peripheral edge portion of the substrate. This arrangement has the operation of enabling the generation of a uniform electric field, restraining the occurrence of variation of the plasma processing characteristic in the outer peripheral edge portion of the substrate and allowing the achievement of uniform plasma processing.

According to a third aspect of the present invention, there is provided the plasma processing apparatus as claimed in the second aspect, wherein the L-figured ring is divided into an outer side surface covering-portion that has a clearance outwardly of the substrate with respect to the outer peripheral edge portion of the substrate, for covering an outer side surface of the outer peripheral edge portion of the substrate and an upper surface covering-portion that has a clearance in a direction of thickness of the substrate with respect to the upper surface of the outer peripheral edge portion of the substrate, for covering the upper surface of the outer peripheral edge portion of the substrate. Providing the divided structure has the operation of simplify the manufacturing.

According to a fourth aspect of the present invention, there is provided the plasma processing apparatus as claimed in the first aspect, wherein the cathode electrode has a substrate contact area which is smaller than the substrate, and the ring is arranged outwardly of the substrate contact area of the cathode electrode and on the cathode electrode and has a bracket-like shape directed in a direction in which a cross-section shape of the ring is able to encompass the outer peripheral edge portion of the substrate. This arrangement has operation similar to that of the second aspect of the present invention.

According to a fifth aspect of the present invention, there is provided the plasma processing apparatus as claimed in the fourth aspect, wherein the bracket-shaped ring is divided into an outer side surface covering-portion, for covering an outer side surface of the outer peripheral edge portion of the substrate, that has a clearance outwardly of the substrate with respect to the outer peripheral edge portion of the substrate and an upper surface covering-portion, for covering the upper surface of the outer peripheral edge portion of the substrate, that has a clearance in a direction of thickness of the substrate with respect to the upper surface of the outer peripheral edge portion of the substrate. This arrangement has operation similar to that of the third aspect of the present invention.

According to a sixth aspect of the present invention, there is provided the plasma processing apparatus as claimed in the third aspect, wherein the upper surface covering-portion is placed on the outer side surface covering-portion so as to be capable of moving the upper surface covering-portion from the outer side surface covering-portion in the thickness direction. Driving the above-mentioned portion has the operation of enabling the conveyance of the substrate to be processed.

According to a seventh aspect of the present invention, there is provided the plasma processing apparatus as claimed in the fifth aspect, wherein the upper surface covering-portion is placed on the outer side surface covering-portion so as to move the upper surface covering-portion from the outer side surface covering-portion in the thickness direction. Providing the clearance between the substrate and the ring has the operation of enabling the generation of an optimum uniform electric field and preventing the change in the impedance of the substrate itself due to the contact of the substrate with the ring.

According to an eighth aspect of the present invention, there is provided the plasma processing apparatus as claimed in the first aspect, wherein a region for encompassing the outer peripheral edge portion of the substrate, approximately has a region of not smaller than 3 mm and not greater than 10 mm for covering the outer peripheral edge of the substrate inwardly of an upper surface of the substrate and approximately has a clearance of not smaller than 0.1 mm and not greater than 0.5 mm with respect to an encompassing surface of the ring and the upper surface of the substrate. This arrangement has the operation of enabling the correction of the change in the impedance due to a change in the thickness configuration of the ring.

According to a ninth aspect of the present invention, there is provided the plasma processing apparatus as claimed in the third aspect, wherein a region for encompassing the outer peripheral edge portion of the substrate, approximately has a region of not smaller than 3 mm and not greater than 10 mm for covering the outer peripheral edge of the substrate inwardly of an upper surface of the substrate and approximately has a clearance of not smaller than 0.1 mm and not greater than 0.5 mm with respect to an encompassing surface of the ring and the upper surface of the substrate. This arrangement has the operation of enabling the correction of the change in the impedance due to a change in the thickness configuration of the ring.

According to a 10th aspect of the present invention, there is provided the plasma processing apparatus as claimed in the fifth aspect, wherein a region for encompassing the outer peripheral edge portion of the substrate, approximately has a region of not smaller than 3 mm and not greater than 10 mm for covering the outer peripheral edge of the substrate inwardly of an upper surface of the substrate and approximately has a clearance of not smaller than 0.1 mm and not greater than 0.5 mm with respect to an encompassing surface of the ring and the upper surface of the substrate. This arrangement has the operation of enabling the correction of the change in the impedance due to a change in the thickness configuration of the ring.

According to an 11th aspect of the present invention, there is provided the plasma processing apparatus as claimed in the first aspect, wherein in a region of the ring for covering the outer peripheral edge of the substrate inwardly of an upper surface of the substrate, the ring has an upper surface tapered in a direction of thickness from an innermost edge portion of the ring outwardly of the ring with respect to a lower surface of the ring.

According to a 12th aspect of the present invention, there is provided the plasma processing apparatus as claimed in the fourth aspect, wherein in a region of the ring for covering the outer peripheral edge of the substrate inwardly of an upper surface of the substrate, the ring has an upper surface tapered in a direction of thickness from an innermost edge portion of the ring outwardly of the ring with respect to a lower surface of the ring.

Next, various kinds of embodiments of the present invention will be described below.

(First Embodiment)

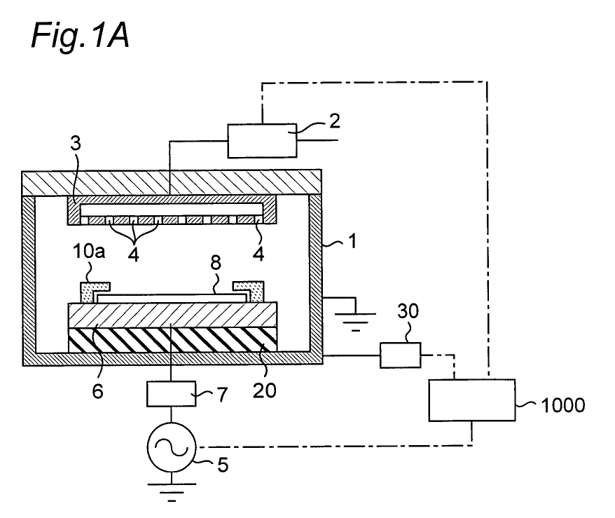

FIGS. 1A, 1B, and 1C are views showing a plasma processing apparatus according to a first embodiment of the present invention.

In FIGS. 1A, 1B, and 1C, a reactive gas (serving as one example of processing gas) of which the flow rate is controlled by a mass flow controller 2 can be supplied from many blowout holes 4 provided for a rectangular anode electrode 3 into a vacuum vessel 1 (serving as one example of a vacuum chamber or a processing chamber) reduced in pressure to a prescribed pressure by evacuating by an evacuating unit 30 such as a vacuum pump. A high-frequency power can be applied from a high-frequency power supply 5 to a rectangular plate-shaped cathode electrode 6, subjected to impedance matching by a matching box 7 provided partway, and supplied into the vacuum vessel 1. A rectangular plate-shaped insulating member 20 is provided between the vacuum vessel 1 and the cathode electrode 6 with the vacuum vessel 1 and the anode electrode 3 earthed.

In the first embodiment, as shown in FIGS. 1B and 1C, the cathode electrode 6 has a substrate placement surface (upper surface) which is relatively larger than a cathode electrode contact area (lower surface) of a substrate 8 to be processed. A ring 10 formed by an insulating material that is preferably ceramic, Duracon (Registered Trademark), quartz, or the like, which is stable even in a plasma is placed substantially on the outer peripheral edge portion of the upper surface (substrate placement surface) of the cathode electrode 6. The ring 10 has an L-figured shape directed in a direction in which its cross-section shape can encompass the outer peripheral edge portion of the substrate 8 while clearances 41 and 42 are provided between the encompassing surface of the ring 10a and the upper surface of the outer peripheral edge portion of the substrate 8 and between the encompassing surface of the ring 10a and the side surface of the outer peripheral edge portion of the substrate 8 to be processed, the ring 10 having a portion which can serve as an outer side surface covering-portion for covering the outer side surface of the outer peripheral edge portion of the substrate 8 and which is a portion having a dimension larger than the thickness of the substrate to be processed; and a remaining upper end portion 10a-1, for covering the upper surface of the outer peripheral edge portion of the substrate 8, protruded generally along the upper surface of the cathode electrode 6 toward the center portion thereof in order to serve as an upper surface covering-portion. The clearance 42 may be not provided whereas at least the clearance 41 is provided between the encompassing surface of the ring 10a and the upper surface of the outer peripheral edge portion of the substrate 8 to be processed.

The encompassing surface of the ring 10a and the upper surface of the outer peripheral edge portion of the substrate 8 are preferably parallel to each other. The encompassing surface of the ring 10a and the side surface of the outer peripheral edge portion of the substrate 8 are preferably parallel to each other.

According to the plasma processing apparatus with such an arrangement, an electric field is generated between the anode electrode 3 and the cathode electrode 6, and the electric field transforms the reactive gas into a plasma. The plasma etches the rectangular plated-shaped substrate 8 placed on the cathode electrode 6. In order to obtain uniformity in the surface of the substrate 8 to be processed, as described above, the rectangular ring 10a, which while encompassing the outer peripheral edge portion of the substrate 8 to be processed, has the clearance 41 at least between the encompassing surface of the ring 10a and the upper surface of the outer peripheral edge of the substrate 8 to be processed, or, preferably, the clearances 41 and 42 between the encompassing surface of the ring 10a and the upper surface of the outer peripheral edge of the substrate 8 and between the encompassing surface of the ring 10a and the outer peripheral edge of the substrate 8 to be processed, are provided on the cathode electrode 6 and operates to correct the etching rate in the neighborhood of the outer peripheral edge portion of the substrate 8 to be processed. This therefore enables the generation of a uniform electric field, and the restraint of the phenomenon of the excessive increase of the plasma sheath in the neighborhood of the outer peripheral edge portion of the substrate 8 to be processed, the restraint of the occurrence of variation of the plasma processing characteristic, and the achievement of uniform plasma processing of the substrate 8 to be processed.

In FIG. 1A, reference numeral 1000 denotes a controller which can control respective operations of the evacuating unit 30, the high-frequency power supply 5, the mass flow controller 2, a substrate conveyance mechanism, a door 15, a substrate conveyance arm 14, and a substrate lift driving device 21 which are described later.

As one example of the reactive gas, a mixed gas of Cl₂ and BCl₃ in a case where an etching-use film of a substrate 8 is formed by titanium or aluminum, a gas of Cl₂ in a case where an etching-use film of a substrate 8 is formed by silicon, and a CF based gas such as CF₄ gas in a case where an etching-use film of a substrate 8 is formed by silicon nitride, can be used. As one example, the size of the substrate 8 is 550 mm×670 mm, the pressure is 15 Pa to 3 Pa depending on kinds of an etching-use film, the high frequency applied from the high-frequency power supply 5 to the cathode electrode 6 is 13.56 MHz, the power is 1000 W to 3000 W, and the power per area is 0.00271 W/mm² to 0.00814 W/mm².

(Second Embodiment)

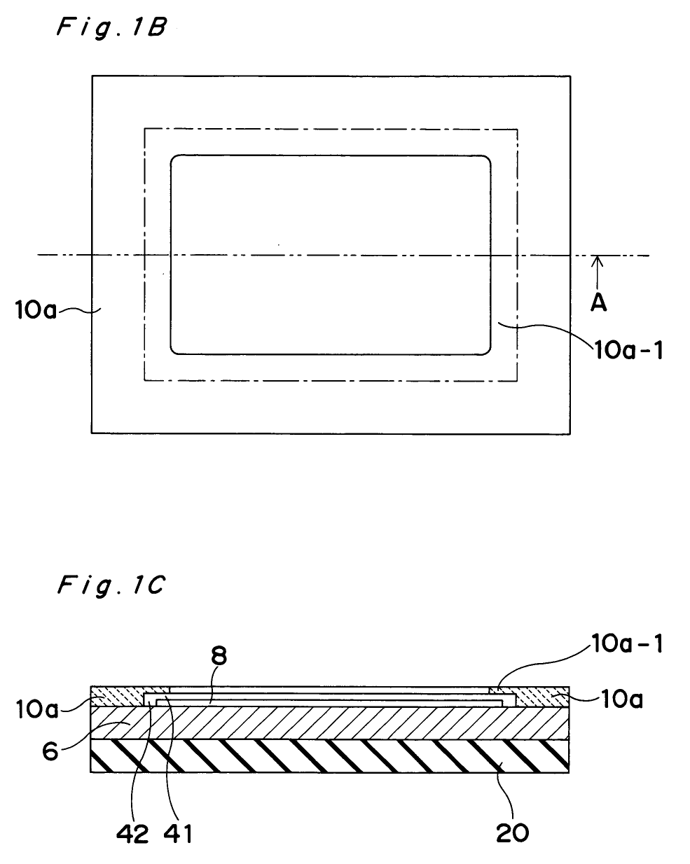

FIG. 2A is a view showing a plasma processing apparatus according to a second embodiment of the present invention, where the neighborhood of the outer peripheral edge portion of a substrate 8 is shown enlarged. In the second embodiment, the different point from the first embodiment in the plasma processing apparatus of FIG. 1A is as follows. That is, the dimension of a substrate contact surface 6a upwardly protruded at the middle portion of the cathode electrode 6A is relatively smaller than the dimension of a cathode electrode contact area of the substrate 8 to be processed, and a ring 10b is arranged substantially outside the surface of the substrate contact surface 6a of the cathode electrode 6A and has a bracket-like shape directed in a direction in which its cross-section shape can encompass the outer peripheral edge portion of the substrate 8 while protruding an upper end portion 10b-1 and a lower end portion 10b-2 generally along the substrate contact area 6a of the cathode electrode 6A toward the center portion thereof and thus providing the clearances 41, 42, and 43 between the encompassing surface of the ring 10b and the upper surface of the outer peripheral edge portion of the substrate 8 to be processed, between the encompassing surface of the ring 10b and the side surface of the outer peripheral edge portion of the substrate 8, and between the encompassing surface of the ring 10b and a lower surface of the outer peripheral edge portion of the substrate 8. The upper end portion 10b-1 is protruded toward the center portion as compared with the lower end portion 10b-2. The upper end portion 10b-1 of the ring 10b covers the upper surface of the outer peripheral edge portion of the substrate 8, the lower end portion 10b-2 covers the lower surface of the outer peripheral edge portion of the substrate 8, and the remaining portion of the ring 10b covers the outer side surface of the outer peripheral edge portion of the substrate 8.

The encompassing surface of the ring 10b and the upper surface of the outer peripheral edge portion of the substrate 8 are preferably parallel to each other. The encompassing surface of the ring 10b and the side surface of the outer peripheral edge portion of the substrate 8 are preferably parallel to each other. The encompassing surface of the ring 10b and the lower surface of the outer peripheral edge portion of the substrate 8 are preferably parallel to each other.

FIGS. 2B and 2C show a modification of the second embodiment, the different point from FIG. 2A is that there is no clearance on the lower surface side of the outer peripheral edge portion of the substrate 8 whereas the other constructions are generally the same as FIG. 2A. That is, the ring 10b has a bracket-like shape directed in a direction in which its cross-section shape can encompass the outer peripheral edge portion of the substrate 8 while protruding the upper end portion 10b-1 and the lower end portion 10b-2 generally along the substrate contact area 6a of the cathode electrode 6A toward the center portion thereof and thus providing the clearances 41 and 42 between the encompassing surface of the ring 10b and the upper surface of the outer peripheral edge portion of the substrate 8 and between the encompassing surface of the ring 10b and the side surface of the outer peripheral edge portion of the substrate 8. The protruding amount of the substrate contact surface 6a-1 of the cathode electrode 6A-1 and the thickness of the lower end portion 10b-2 of the ring 10b are generally the same as each other, so that the lower surface of the outer peripheral edge portion of the substrate 8 is located on both of the substrate contact surface 6a-1 of the cathode electrode 6A-1 and the lower end portion 10b-2 of the ring 10b, resulting in no clearance on the lower surface side of the outer peripheral edge portion of the substrate 8.

Either of the above-mentioned FIG. 2A, and FIGS. 2B and 2C enables the generation of a uniform electric field, the restraint of the phenomenon of the excessive increase of the plasma sheath in the neighborhood of the outer peripheral edge portion of the substrate 8 to be processed, the restraint of the occurrence of variation of the plasma processing characteristic in the outer peripheral edge portion of the substrate 8 and the achievement of uniform plasma processing.

(Third Embodiment)

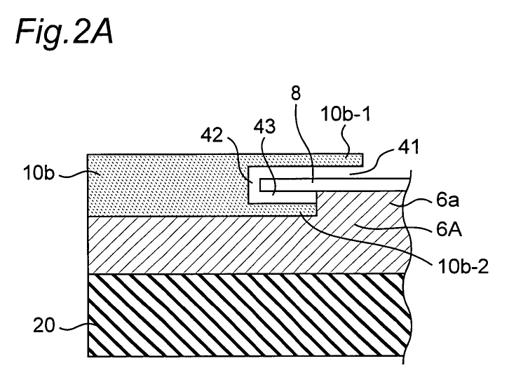

FIG. 3A is a view showing a plasma processing apparatus of a third embodiment of the present invention, where the neighborhood of the outer peripheral edge portion of a substrate is shown enlarged. FIG. 3A shows a structure in which the L-figured ring 10a of FIGS. 1A-1C is constructed as a ring 10g which provided on the cathode electrode 6 and has such a construction that can be divided into: an outer side surface covering-portion 10c that has a thickness larger than the thickness of the substrate 8 and has a clearance 42 outwardly of the substrate 8 with respect to the outer peripheral edge portion of the substrate 8; and an upper surface covering-portion 10d that is protruded toward the center portion thereof as compared with the outer side surface covering-portion 10c and has a clearance 41 in the direction of thickness of the substrate 8 with respect to the upper surface of the outer peripheral edge portion of the substrate 8. The upper surface covering-portion 10d covers the upper surface of the outer peripheral edge portion of the substrate 8 and the outer side surface covering-portion 10c covers the outer side surface of the outer peripheral edge portion of the substrate 8.

FIG. 3B shows a structure in which in a modification of the third embodiment, the bracket-shaped ring 10b of FIG. 2A is constructed as a ring 10h which provided on the cathode electrode 6A and has such a construction that can be divided into: an outer side surface and lower surface covering-portion 10e that has a thickness larger than the thickness of the substrate 8 and has clearances 42 and 43 outwardly and downwardly (lower surface side direction) of the substrate 8 with respect to the outer peripheral edge portion of the substrate 8; and an upper surface covering-portion 10f that is protruded toward the center portion thereof as compared with the outer side surface and lower surface covering-portion 10e and has a clearance 41 in the direction of thickness of the substrate 8 with respect to the upper surface of the outer peripheral edge portion of the substrate 8. The upper surface covering-portion 10f of the ring 10h covers the upper surface of the outer peripheral edge portion of the substrate 8 and the outer side surface and lower surface covering-portion 10e covers the outer side surface and the lower surface of the outer peripheral edge portion of the substrate 8.

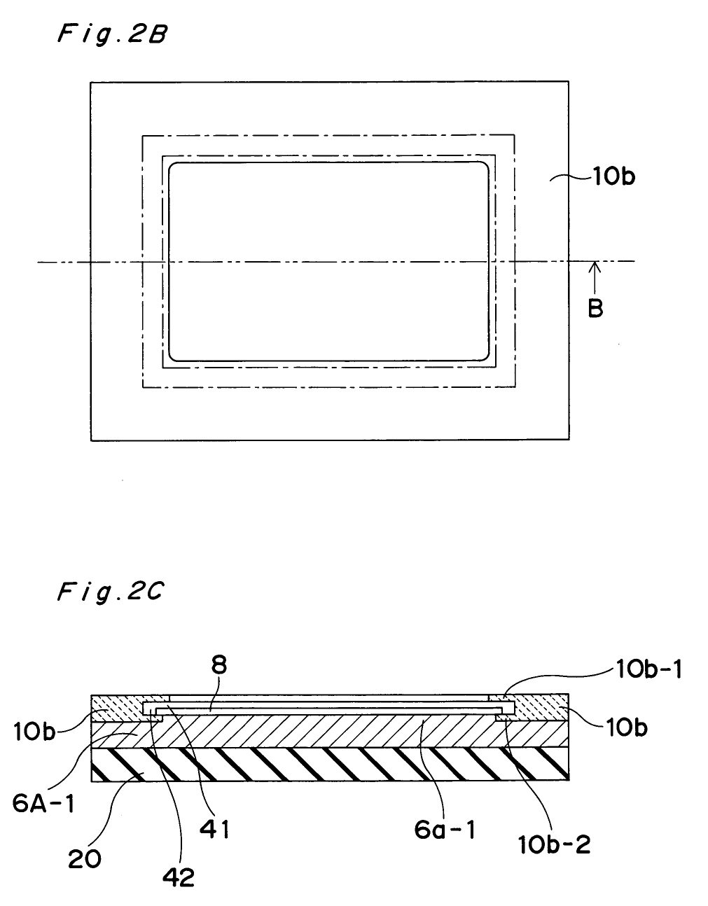

Either of the above-mentioned FIGS. 3A and 3B enables the generation of a uniform electric field and the restraint of the phenomenon of the excessive increase of the plasma sheath in the neighborhood of the outer peripheral edge portion of the substrate 8. Therefore, the occurrence of variation of the plasma processing characteristic in the outer peripheral edge portion of the substrate 8 can be restrained, and uniform plasma processing can be achieved. Moreover, by virtue of the provision of the divided structure, the manufacturing is simple. By driving the upper surface covering-portion 10d or 10f, which has the clearance 41 in the direction of thickness of the substrate 8, with respect to the upper surface of the outer peripheral edge portion of the substrate 8 in the vacuum vessel 1 by means of a drive mechanism as shown in FIGS. 4A and 4B, the substrate 8 can be conveyed.

FIGS. 4A and 4B are views showing one example of the substrate conveyance mechanism for enabling the conveyance of the substrate 8. Here, a case where the division system ring 10h shown in FIG. 3B and having the outer side surface and lower surface covering-portion 10e and the upper surface covering-portion 10f is placed on the cathode electrode 6A-1 having the substrate contact surface 6a-1 with no clearance 43 on the lower surface side will be described.

First of all, when a substrate 8 to be processed is placed on the cathode electrode 6A-1 inside the vacuum vessel 1, the upper surface covering-portion 10f of the ring 10h where four support bars 13 are attached onto the shorter sides of the rectangular shape of the ring 10h is moved up by ring elevation units 11 serving as one example of the drive mechanism. Each ring elevation unit 11 has a drive device 22 such as a piston or a motor, and a contact plate 24 with an L-figured shape cross-section which is connected to an upper end of a rod 23 capable of being driven by the drive device 22, so that the contact plate 24 is moved up and down by driving of the drive device 22. By simultaneously bring the contact plates 24 into contact with the four support bars 13 upon upward movement of the contact plates 24 by the drive devices 22 and thus lifting the four support bars 13, the upper surface covering-portion 10f of the ring 10h is moved upward in a generally parallel motion to an upper end position shown by a one dot-dash line from a placement position shown by a solid line in FIG. 4B.

Next, in a state where the U-shaped substrate conveyance arm 14 on which the substrate 8 is placed at a retreat position II passes from a preparing chamber outside and adjacent to the vacuum vessel 1, through the preparatorily opened door 15, into the vacuum vessel 1 where the upper surface covering-portion 10f of the ring 10h is located at the upper end position shown by the one dot-dash line. Then, the U-shaped substrate conveyance arm 14 is inserted into a space between the upper surface covering-portion 10f of the ring 10h and the cathode electrode 6A-1 which is an insert position I.

Subsequently, for example, four substrate elevation pins 12 are moved up from lower end positions shown by solid lines to upper end positions shown by one dot-dash lines by driving of four substrate lift driving devices 21 such as pistons to lift the substrate 8 on the substrate conveyance arm 14 from the substrate conveyance arm 14.

Thereafter, the substrate conveyance arm 14 moves out of the vacuum vessel 1, and the door 15 is closed.

Subsequently, the substrate elevation pins 12 are moved down by driving of the four substrate lift driving devices 21 to place the substrate 8 on the cathode electrode 6A-1, and the upper surface covering-portion 10f of the ring 10h is finally moved down by the drive devices 22 to allow the outer peripheral edge portion of the substrate 8 to be covered with the upper surface covering-portion 10f of the ring 10h.

After plasma processing is completed, the operation reverse to the above operation is carried out.

That is, the upper surface covering-portion 10f of the ring 10h covering the outer peripheral edge portion of the substrate 8 is moved upward to the upper end position by the drive devices 22

Subsequently, the substrate elevation pins 12 are moved up from the lower end positions shown by the solid lines to the upper end positions shown by the one dot-dash lines by driving of the substrate lift driving devices 21, and thus, the substrate 8 on the cathode electrode 6A-1 is lifted from the cathode electrode 6A-1.

Subsequently, the substrate conveyance arm 14 passes through the preparatorily opened door 15 from the preparing chamber adjacent to the vacuum vessel 1 and then is inserted into the vacuum vessel 1 to be inserted to the insert position I between the lifted substrate 8 and the cathode electrode 6A-1.

Subsequently, the substrate elevation pins 12 are moved down to place the substrate 8 on the substrate conveyance arm 14 and are moved down to the lower end positions.

Subsequently, the substrate conveyance arm 14 on which the substrate 8 is placed is moved outward of the vacuum vessel 1 and then the door 15 is closed.

It is to be noted that the mass flow controller 2, the anode electrode 3, the gas blowout holes 4, the high-frequency power supply 5, the matching box 7, and the like of FIG. 1A are not shown in FIGS. 4A and 4B for the sake of simplicity.

(Fourth Embodiment)

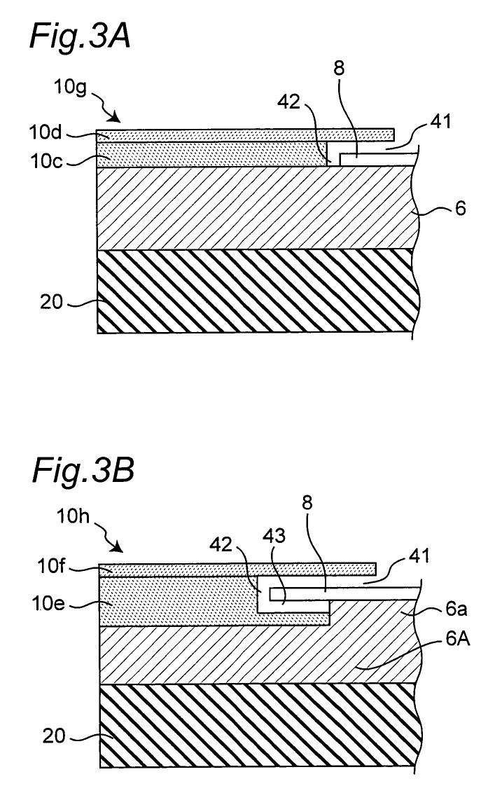

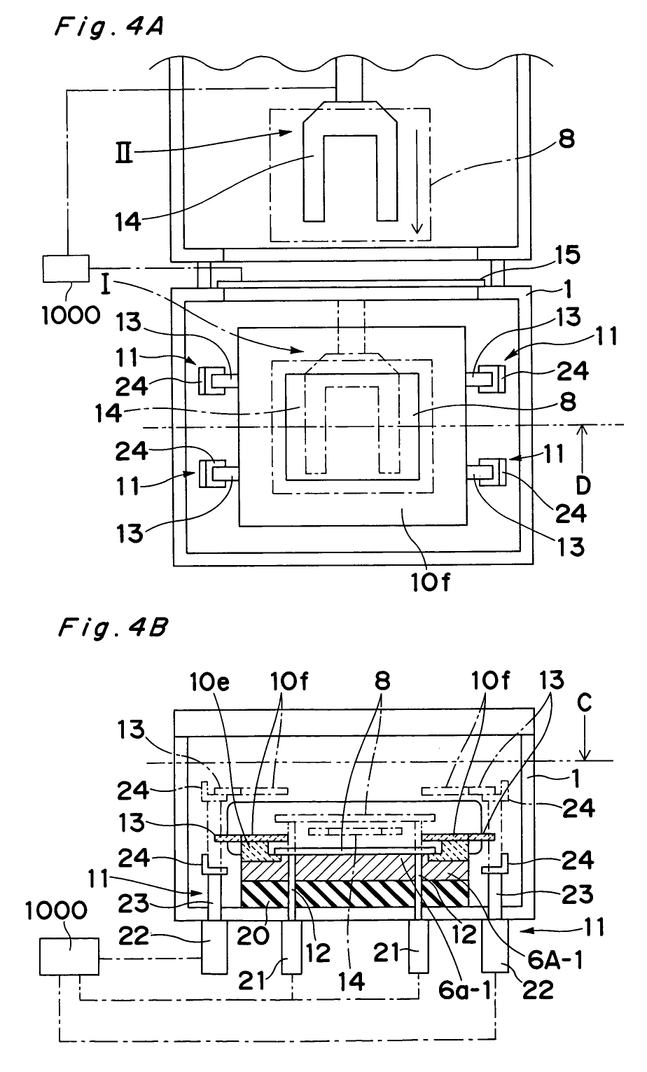

FIG. 5 is a view showing a plasma processing apparatus according to a fourth embodiment of the present invention, where the neighborhood of the outer peripheral edge portion of a substrate 8 is shown enlarged taking the second embodiment of FIG. 2A as an example. The fourth embodiment specifies distances of the clearances 41 and 42 in the second embodiment and is characterized in that, when a portion ranging from the upper surface of the substrate 8 to the lower surface of the substrate 8 is squarely viewed, a region D covering the outer peripheral edge portion of the substrate 8 inwardly of an upper surface of the substrate 8 (toward the center portion thereof) is not smaller than about 1 mm and not greater than 10 mm, and dimensions d1 and d2 of the clearances 41 and 42 between the encompassing surface of the ring 10b and the upper surface of the outer peripheral edge of the substrate 8 and between the encompassing surface of the ring 10b and the outer peripheral edge of the substrate 8 are not smaller than about 0.1 mm and not greater than 1.0 mm. In either case, by virtue of the provision of these distance dimensions, a uniform electric field can be optimally generated, and the phenomenon of the excessive increase of the plasma sheath in the neighborhood of the outer peripheral edge portion of the substrate 8 can be restrained. If a ring inner peripheral thickness d3 of the upper end portion 10b-1 of the ring 10b is not greater than 3 mm, then the distortion of the plasma sheath due to the thickness of the ring 10b can be ignored.

For the above reasons, the variation of the plasma processing characteristic in the outer peripheral edge portion of the substrate 8 can be more surely restrained, and uniform plasma processing can be more surely achieved.

(Fifth Embodiment)

FIG. 5 is a view showing a plasma processing apparatus of a fifth embodiment of the present invention, where the neighborhood of the outer peripheral edge portion of a substrate 8 is shown enlarged taking the second embodiment of FIG. 2A as an example. When an upper surface covering-portion 10k of a ring 10j ranging from the upper surface of the substrate 8 to the lower surface of the substrate 8 is squarely viewed, the ring 10i in the region covering the outer peripheral edge of the substrate 8 inwardly of the upper surface of the substrate 8 has a the upper surface covering-portion 10k tapered so as to increase the thickness in a direction of thickness from an innermost edge portion of the upper surface covering-portion 10k outwardly of the upper surface covering-portion 10k with respect to the lower surface of the upper surface covering-portion 10k. Normally, the material that forms the ring 10j preferably is an insulating material of ceramic, Duracon (Registered Trademark), quartz, or the like, which is stable even in a plasma, whereas these are materials having brittleness. Therefore, when the ring inner edge thickness d3 of the upper surface covering-portion 10k is set not greater than 3 mm, it is very highly possible that the material is damaged during maintenance, mounting, and dismounting of the ring 10j or in a similar case with taking the practical use into consideration. Therefore, the thickness must be secured in terms of strength. However, by providing the configuration tapered in the direction of thickness as described hereinabove, the impedance due to the change in the configuration of the ring thickness can also be corrected. This arrangement enables the generation of an optimum uniform electric field and the restraint of the phenomenon of the excessive increase of the plasma sheath in the neighborhood of the outer peripheral edge portion of the substrate 8. For this reason, the variation of the plasma processing characteristic in the outer peripheral edge portion of the substrate 8 can be restrained, and uniform plasma processing can be achieved. It is to be noted that the taper angle θ of the upper surface covering-portion 10k of the ring 10j preferably is 10° to 30° taking the strength of the ring inner edge portion of the upper surface covering-portion 10k into consideration.

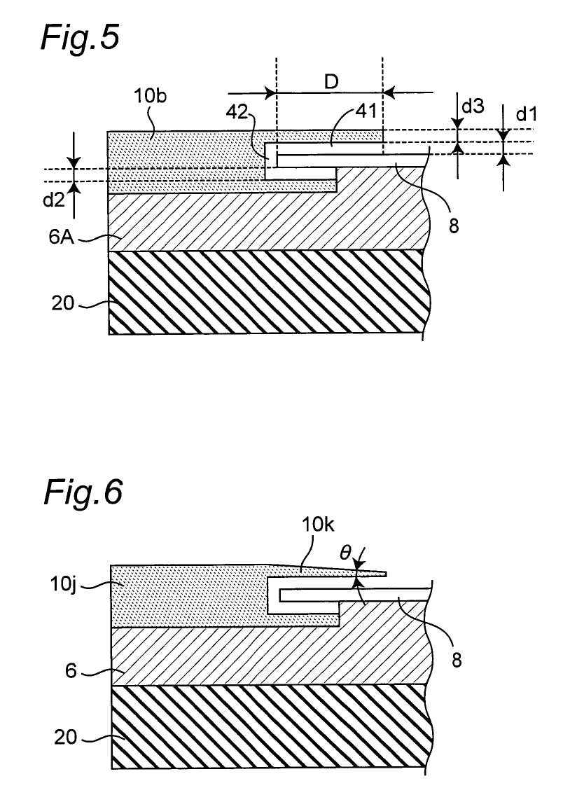

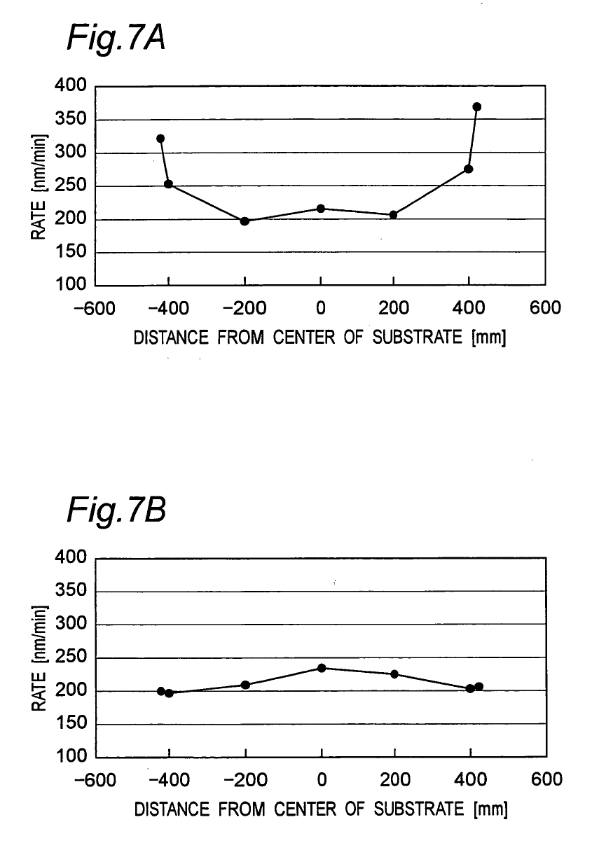

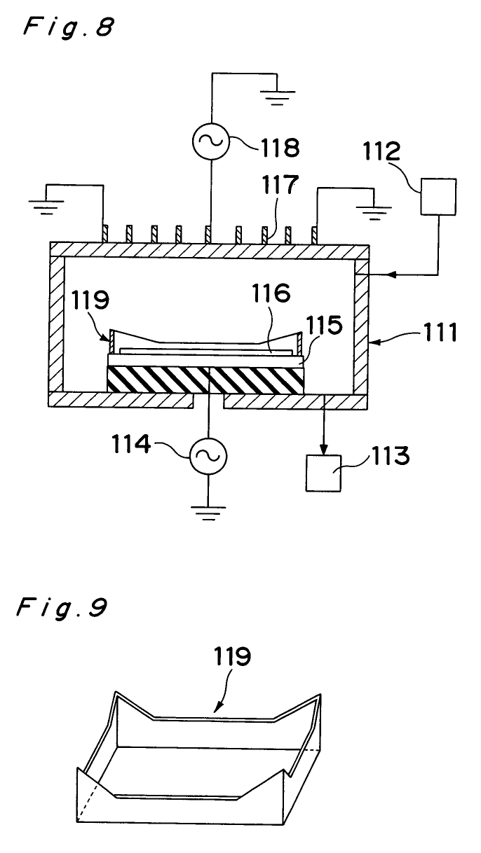

FIG. 7A shows an etching rate when a silicon nitride film substrate is etched in Ar gas by means of a dry etching apparatus for LCD capable of coping with a 550 mm×670 mm substrate in a plasma processing apparatus to which the present invention is not adopted (processing conditions: Ar gas of 1200 sccm, pressure of 0.5 Pa, and applied power of 4500 W). FIG. 7B shows an etching rate when a silicon nitride film substrate is etched in Ar gas by means of a dry etching apparatus for LCD capable of coping with a 550 mm×670 mm substrate in the plasma processing apparatus shown in the first embodiment of the present invention (processing conditions: Ar gas of 1200 sccm, pressure of 0.5 Pa, and applied power of 4500 W). Etching the silicon nitride film in Ar gas, which is almost ionic etching, is equivalent to the measurement of a sheath distribution on the surface of the substrate 8.

As a result, it can be confirmed that the etching rate of the outer peripheral edge portion of the substrate 8 is restrained in the case where the plasma processing apparatus of the first embodiment of the present invention is used in FIG. 7B in contrast to the fact that the etching rate of the outer peripheral edge portion of the substrate is excessively increased in the case where the present invention is not adopted shown in FIG. 7A.

Therefore, according to the plasma processing apparatus in the various embodiments of the present invention, an electric field can be uniformly generated in comparison with the prior art example, and the phenomenon of the excessive increase of the plasma sheath in the neighborhood of the outer peripheral edge portion of the substrate can be restrained. This has proved that the variation of the plasma processing characteristic in the outer peripheral edge portion of the substrate has been able to be restrained, and uniform plasma processing has been able to be achieved.

In addition, combining any arbitrary embodiments together appropriately from among the foregoing various embodiments allows their respective effects to be produced.

The plasma processing apparatus of the present invention is able to correct the change in impedance ascribed to the change in the configuration due to the thickness of the substrate and the material of the substrate by virtue of the provision of the ring that encompasses the outer peripheral edge portion of the substrate. Furthermore, a uniform electric field can be generated by virtue of the provision of the clearance between the substrate and the encompassing surface of the ring. Such an arrangement enables the restraint of the phenomenon of the excessive increase of the plasma sheath in the neighborhood of the outer peripheral edge portion of the substrate, the restraint of the occurrence of variation of the plasma processing characteristic in the outer peripheral edge portion of the substrate, and the achievement of uniform processing.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

What is claimed is:

1. A plasma processing apparatus, for introducing a processing gas into a processing chamber and exciting a plasma in the processing chamber to carry out plasma processing on a substrate to be processed placed on a cathode electrode inside the processing chamber,
the apparatus comprising a ring for encompassing an outer peripheral edge portion of the substrate in proximity to the outer peripheral edge portion of the substrate, the ring having a clearance between its encompassing surface and an upper surface of the substrate.

2. The plasma processing apparatus as claimed in claim 1, wherein the cathode electrode has a substrate placement surface having larger than the substrate, and the ring is placed on the substrate placement surface of the cathode electrode and has an L-figured shape directed in a direction in which a cross-section shape of the ring is able to encompass the outer peripheral edge portion of the substrate.

3. The plasma processing apparatus as claimed in claim 2, wherein the L-figured ring is divided into an outer side surface covering-portion that has a clearance outwardly of the substrate with respect to the outer peripheral edge portion of the substrate, for covering an outer side surface of the outer peripheral edge portion of the substrate and an upper surface covering-portion that has a clearance in a direction of thickness of the substrate with respect to the upper surface of the outer peripheral edge portion of the substrate, for covering the upper surface of the outer peripheral edge portion of the substrate.

4. The plasma processing apparatus as claimed in claim 1, wherein the cathode electrode has a substrate contact area which is smaller than the substrate, and the ring is arranged outwardly of the substrate contact area of the cathode electrode and on the cathode electrode and has a bracket-like shape directed in a direction in which a cross-section shape of the ring is able to encompass the outer peripheral edge portion of the substrate.

5. The plasma processing apparatus as claimed in claim 4, wherein the bracket-shaped ring is divided into an outer side surface covering-portion, for covering an outer side surface of the outer peripheral edge portion of the substrate, that has a clearance outwardly of the substrate with respect to the outer peripheral edge portion of the substrate and an upper surface covering-portion, for covering the upper surface of the outer peripheral edge portion of the substrate, that has a clearance in a direction of thickness of the substrate with respect to the upper surface of the outer peripheral edge portion of the substrate.

6. The plasma processing apparatus as claimed in claim 3, wherein the upper surface covering-portion is placed on the outer side surface covering-portion so as to be capable of moving the upper surface covering-portion from the outer side surface covering-portion in the thickness direction.

7. The plasma processing apparatus as claimed in claim 5, wherein the upper surface covering-portion is placed on the outer side surface covering-portion so as to move the upper surface covering-portion from the outer side surface covering-portion in the thickness direction.

8. The plasma processing apparatus as claimed in claim 1, wherein a region for encompassing the outer peripheral edge portion of the substrate, approximately has a region of not smaller than 3 mm and not greater than 10 mm for covering the outer peripheral edge of the substrate inwardly of an upper surface of the substrate and approximately has a clearance of not smaller than 0.1 mm and not greater than 0.5 mm with respect to an encompassing surface of the ring and the upper surface of the substrate.

9. The plasma processing apparatus as claimed in claim 3, wherein a region for encompassing the outer peripheral edge portion of the substrate, approximately has a region of not smaller than 3 mm and not greater than 10 mm for covering the outer peripheral edge of the substrate inwardly of an upper surface of the substrate and approximately has a clearance of not smaller than 0.1 mm and not greater than 0.5 mm with respect to an encompassing surface of the ring and the upper surface of the substrate.

10. The plasma processing apparatus as claimed in claim 5, wherein a region for encompassing the outer peripheral edge portion of the substrate, approximately has a region of not smaller than 3 mm and not greater than 10 mm for covering the outer peripheral edge of the substrate inwardly of an upper surface of the substrate and approximately has a clearance of not smaller than 0.1 mm and not greater than 0.5 mm with respect to an encompassing surface of the ring and the upper surface of the substrate.

11. The plasma processing apparatus as claimed in claim 1, wherein in a region of the ring for covering the outer peripheral edge of the substrate inwardly of an upper surface of the substrate, the ring has an upper surface tapered in a direction of thickness from an innermost edge portion of the ring outwardly of the ring with respect to a lower surface of the ring.

12. The plasma processing apparatus as claimed in claim 4, wherein in a region of the ring for covering the outer peripheral edge of the substrate inwardly of an upper surface of the substrate, the ring has an upper surface tapered in a direction of thickness from an innermost edge portion of the ring outwardly of the ring with respect to a lower surface of the ring.
